(19) United States
(12) Patent Application Publication
(10) Pub. No.: US 2023/0035216 A1
(43) Pub. Date: Feb. 2, 2023

(54) THREE-DIMENSIONAL ARTIFICIAL NEURAL NETWORK ACCELERATOR AND METHODS OF FORMING THE SAME

(71) Applicant: Taiwan Semiconductor Manufacturing Company Limited, Hsinchu (TW)

(72) Inventor: Oreste MADIA, Hsinchu (TW)

(21) Appl. No.: 17/569,869

(22) Filed: Jan. 6, 2022

Related U.S. Application Data
(60) Provisional application No. 63/227,571, filed on Jul. 30, 2021.

(51) Int. Cl. G06N 3/063

(52) U.S. Cl. CPC G06N 3/063

(57) ABSTRACT

A network computation device includes a stack of a plurality of arrays of magnetic tunnel junctions that are spaced apart along a stack direction, and at least one filament-forming dielectric material layer located between each vertically neighboring pair of arrays of magnetic tunnel junctions selected from the plurality of magnetic tunnel junctions.

### RELATED APPLICATIONS

This application claims the benefit of priority from U.S. Provisional Application No. 63/227,571 titled “Monolithic 3D Reconfigurable Artificial Neural Network Accelerator and Methods for Forming the Same” and filed on Jul. 30, 2021, the entire contents of which are incorporated herein by reference for all purposes.

### BACKGROUND

Device-centric neuromorphic computing has been difficult to realize because memory functions and threshold response functions need to be concurrently provided in a physically implemented computing device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a first exemplary structure including an alternating stack of arrays of magnetic tunnel junctions and filament-forming dielectric material layers according to an embodiment of the present disclosure.

FIG. 1B is a vertical cross-sectional view of a portion of the first exemplary structure of FIG. 1A.

FIG. 1C is a horizontal cross-sectional view of the portion of the first exemplary structure of FIG. 1B.

FIG. 2 is a vertical cross-sectional view of a portion of an alternative embodiment of the first exemplary structure.

FIG. 3 is a schematic view of an exemplary configuration of the first exemplary structure.

FIG. 4A is a perspective view of a second exemplary structure including an alternating stack of arrays of magnetic tunnel junctions and filament-forming dielectric material layers according to an embodiment of the present disclosure.

FIG. 4B is a vertical cross-sectional view of a portion of the second exemplary structure of FIG. 4A.

FIG. 4C is a horizontal cross-sectional view of the portion of the second exemplary structure of FIG. 4B.

FIG. 5A is a vertical cross-sectional view of a first alternative embodiment of a magnetic tunnel junction according to an embodiment of the present disclosure.

FIG. 5B is a horizontal cross-sectional view along the horizontal plane B-B′ of the first alternative embodiment of the magnetic tunnel junction of FIG. 5A.

FIG. 6A is a vertical cross-sectional view of a second alternative embodiment of a magnetic tunnel junction according to an embodiment of the present disclosure.

FIG. 6B is a topo-down view of the second alternative embodiment of the magnetic tunnel junction of FIG. 6B.

FIG. 7A is a vertical cross-sectional view of a third alternative embodiment of a magnetic tunnel junction according to an embodiment of the present disclosure.

FIG. 7B is a topo-down view of the third alternative embodiment of the magnetic tunnel junction of FIG. 7B.

FIG. 8 is a flowchart that illustrates the general processing steps for operating a network computation device according to an embodiment of the present disclosure.

FIG. 9 is a flowchart that illustrates the general processing steps for manufacturing a network computation device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

Machine learning accelerators known in the art focus on speeding the computation of the mathematic representation of neural network. This approach requires significant energy consumption of the input signal, output signals, and weight inputs during the process of digital-to-analog conversion and analog-to-digital conversion in order to enable calculation in a machine learning accelerator. Thus, a significant fraction of the energy need to operate machine learning accelerators is consumed during signal conversion processes.

Embodiments of the present disclosure provide a three-dimensional monolithic reconfigurable network computation device that may be used for artificial neural network (ANN) mapping calculations or other network-based computations. Weight inputs may be downloaded directly into a network computation device, which may be subsequently used to perform an inference operation for a specific model of choice as programmed by the weight inputs. The reconfigurable nature of the network computation device of various embodiments of the present disclosure allows for repeated use of the network computation device on different ANN models, and reduces weight redundancy. The network computation device of various embodiments of the present disclosure may include a die, or as a component of a die, such as semiconductor die.

According to an aspect of the present disclosure, the circuitry of the network computation device of the present disclosure may include magnetic tunnel junctions (MTJs), which may be pillar-type magnetic tunnel junctions. The magnetic tunnel junctions of the network computation device may represent binary neurons. Layers including a respective array of magnetic tunnel junctions are interlaced with resistive memory material layers such as filament-forming dielectric material layers. For example, the filament-forming dielectric material layers may use a same material as the resistive memory materials that are typically used in resistive random access memory (RRAM) devices. Conductive filaments formed within the filament-forming dielectric material layers, as formed between neighboring pairs of magnetic tunnel junctions, may represent synapses between neurons in a neural network model. The strength of the filamentary connections may be variable depending on the applied voltage and the arrangement of the magnetic tunnel junctions. The variable strength of these filamentary connections may be encoded as synaptic weights in the machine learning model. The filamentary connections may be reversed by application of reset voltages. Thus, the network computation device of various embodiments of the present disclosure may provide for the resetting and/or reconfiguring of the filamentary connections for reuse for different types of calculations. Various aspect of the details of the present disclosure are described in detail herebelow with reference to accompanying drawings.

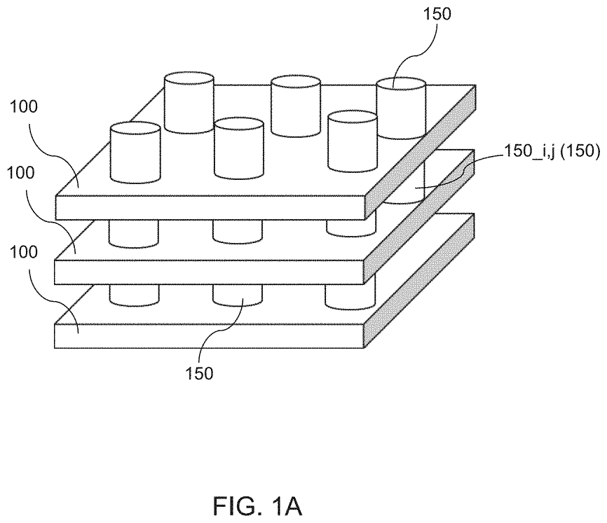

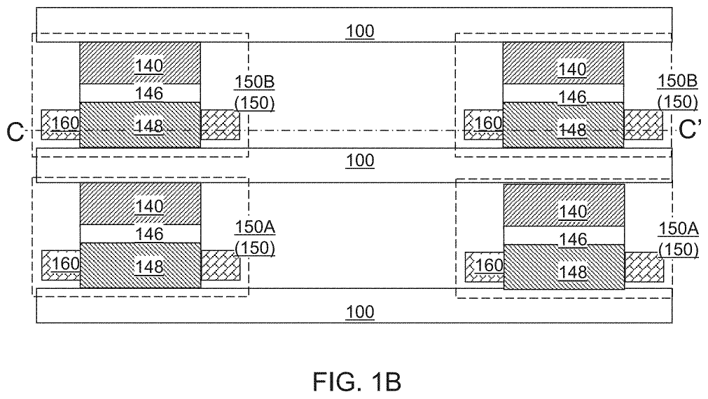

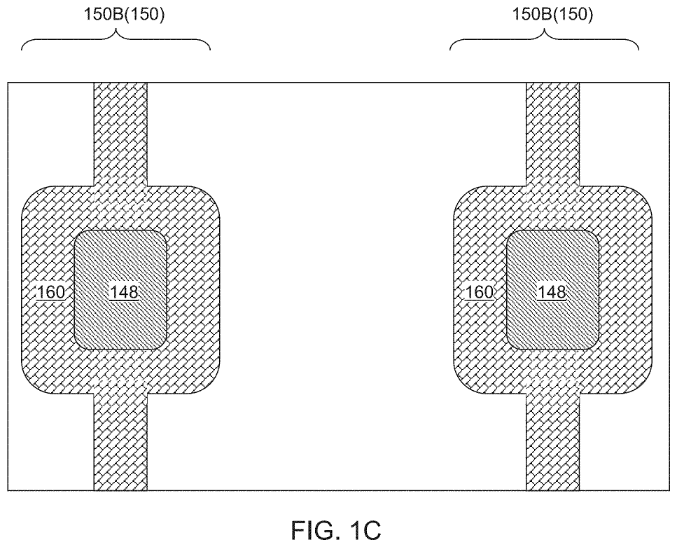

Referring to FIGS. 1A-1C, a first exemplary structure including an alternating stack of arrays of magnetic tunnel junctions 150 and filament-forming dielectric material layers 100 according to an embodiment of the present disclosure is illustrated. The first exemplary structure may include a network computation device in which the magnetic tunnel junctions 150 provide programmable resistance to electrical current flow. Specifically, the magnetic tunnel junctions 150 may be in a parallel state in which a magnetization of a free magnetization layer 148 may be parallel to a fixed magnetization of a reference magnetization layer 140 to provide a low magnetoresistance state (and hence, a high electrical conductance), or the magnetization of the free magnetization layer 148 may be antiparallel to the fixed magnetization of the reference magnetization layer 140 to provide a high magnetoresistance state (and hence, a low electrical conductance). At least a subset, or all, of the magnetic tunnel junctions 150 may be programmable into a respective parallel state or a respective antiparallel state.

The first exemplary structure may include a stack of a plurality of arrays of magnetic tunnel junctions 150 that are spaced apart along a stack direction (such as a vertical direction), and at least one filament-forming dielectric material layer 100 located between each vertically neighboring pair of arrays of magnetic tunnel junctions 150 selected from the plurality of magnetic tunnel junctions 150.

Each of the at least one filament-forming dielectric material layer 100 comprises, and/or consists essentially of, a filament-forming dielectric material, i.e., a dielectric material that forms conductive filaments therein upon application of an electrical bias thereacross. In one embodiment, each of the at least one filament-forming dielectric material layer 100 comprises, and/or consists essentially of, hafnium oxide, titanium oxide (TiO₂), zirconium oxide (ZrO₂), tantalum oxide (TaO₂), strontium titanium oxide (SrTiO₃), nickel oxide (NiO), and silicon oxide (SiO₂). The at least one filament-forming dielectric material layer 100 may include a plurality of filament-forming dielectric material layers 100, i.e., two or more filament-forming dielectric material layers 100. Each filament-forming dielectric material layer 100 may have a thickness in a range from 1 nm to 20 nm, such as from 2 nm to 10 nm, although lesser and greater thicknesses may also be used. Each filament-forming dielectric material layer 100 may be deposited by a conformal or non-conformal deposition process such as a physical vapor deposition (PVD) process or a chemical vapor deposition (CVD) process, a plasma-enhanced chemical vapor deposition (PECVD) process, a low pressure chemical vapor deposition (LPCVD) process, an atomic layer deposition (ALD) process, a plasma-enhanced atomic layer deposition (PEALD) process, or a molecular beam deposition (MBE) process. In some embodiments, a lower metallic liner may be optionally provided on a bottom surface of a filament-forming dielectric material layer 100, and/or an upper metallic liner may be optionally provided on a top surface of a filament-forming dielectric material layer 100. If employed, the lower metallic liner and/or the upper metallic liner may enhance filament formation within the filament-forming dielectric material layer 100.

The total number of the at least one filament-forming dielectric material layer 100 may be less than the total number of the arrays of magnetic tunnel junctions 150 by 1, may be equal to the total number of the arrays of magnetic tunnel junctions 150, or may be greater than the total number of the arrays of magnetic tunnel junctions 150 by 1. The stack of the plurality of arrays of magnetic tunnel junctions 150 and the at least one filament-forming dielectric material layer 100 may begin with an array of magnetic tunnel junctions 150 or may begin with a filament-forming dielectric material layer 100 at the bottom, and may terminate with an array of magnetic tunnel junctions 150 or may begin with a filament-forming dielectric material layer 100 at the top. In one embodiment, the stack of the plurality of arrays of magnetic tunnel junctions 150 and the at least one filament-forming dielectric material layer 100 may include an alternating stack of the plurality of arrays of magnetic tunnel junctions 150 and a plurality of filament-forming dielectric material layers 100 that alternate along the stack direction, such as the vertical direction.

The arrays of magnetic tunnel junctions 150 may be vertically spaced from one another along a stack direction, such as a vertical direction. For example, the arrays of magnetic tunnel junctions 150 may comprise an array of first magnetic tunnel junctions 150A located at a first level, and an array of second magnetic tunnel junctions 150B located at a second level that overlies or underlies the first level.

In one embodiment, each magnetic tunnel junction 150 selected from the plurality of arrays of magnetic tunnel junctions 150 comprises a reference magnetization layer 140, a nonmagnetic tunnel barrier layer 146, and a free magnetization layer 148 having two preferred magnetization directions that are parallel or antiparallel to a fixed magnetization direction of the reference magnetization layer 140. In one embodiment, the fixed magnetization direction of each of the magnetic tunnel junctions 150 may be a horizontal direction along which the fixed magnetization of each of the reference magnetization layers 140 may be aligned, for example, by applying an external initializing magnetic field. The easy direction of magnetization of the reference magnetization layers 140 may be along the horizontal direction, and the external initializing magnetic field may be applied after manufacture of the first exemplary structure to orient all fixed magnetization directions of the reference magnetization layers 140 along the easy direction of magnetization.

In one embodiment, each array of magnetic tunnel junctions 150 may be formed by sequentially depositing, bottom up or top down, a blanket (unpatterned) layer stack that includes a free magnetization material layer, a nonmagnetic tunnel barrier material layer, and a fixed magnetization material layer, and by patterning the blanket layer stack into an array of pillar structures. Each pillar structure comprises a magnetic tunnel junction 150. In one embodiment, sidewalls of a free magnetization layer 148, a nonmagnetic tunnel barrier layer 146, and a reference magnetization layer 140 may be vertically coincident, i.e., may be located within a same vertical plane such as a cylindrical vertical plane.

Each free magnetization layer 148 may include a hard ferromagnetic material such as Co, CoFe, CoFeB, CoFeTa, NiFe, CoPt, CoFeNi, etc. Other suitable materials within the contemplated scope of disclosure may also be used. The thickness of each free magnetization layer 148 may be in a range from 1 nm to 20 nm, such as from 2 nm to 10 nm, although lesser and greater thicknesses may also be used.

Each nonmagnetic tunnel barrier layer 146 may include a tunneling barrier material, which may be an electrically insulating material having a thickness that allows electron tunneling. For example, each nonmagnetic tunnel barrier layer 146 may include magnesium oxide (MgO), aluminum oxide (Al₂O₃), or a spinel material. Other suitable materials within the contemplated scope of disclosure may also be used. The thickness of each nonmagnetic tunnel barrier layer 146 may be 0.7 nm to 2 nm, although lesser and greater thicknesses may also be used.

Each reference magnetization layer 140 may include a hard ferromagnetic material such as Co, CoFe, CoFeB, CoFeTa, NiFe, CoPt, CoFeNi, etc. Other suitable materials within the contemplated scope of disclosure may also be used. The thickness of each reference magnetization layer 140 may be in a range from 1 nm to 20 nm, such as from 2 nm to 10 nm, although lesser and greater thicknesses may also be used.

Each array of magnetic tunnel junctions 150 comprises a one-dimensional array of magnetic tunnel junctions 150 or a two-dimensional array of magnetic tunnel junctions 150. In one embodiment, each array of magnetic tunnel junctions 150 may comprise a plurality of magnetic tunnel junctions 150. In one embodiment, each array of magnetic tunnel junctions 150 may include a periodic two-dimensional array of magnetic tunnel junctions 150 such as a rectangular array of magnetic tunnel junctions 150 or a hexagonal array of magnetic tunnel junctions 150. In one embodiment, the array of magnetic tunnel junctions 150 may have the same two-dimensional periodicity. In one embodiment, each array of magnetic tunnel junctions 150 may have a first periodicity along a first horizontal direction and a second horizontal direction that is different from the first horizontal direction. In embodiments in which the periodic two-dimensional arrays of magnetic tunnel junctions 150 includes rectangular arrays, the second horizontal direction may be perpendicular to the first horizontal direction. In embodiments in which the periodic two-dimensional arrays of magnetic tunnel junctions 150 comprise hexagonal arrays, the second horizontal direction may not be perpendicular to the first horizontal direction.

The first periodicity may be in a range from 10 nm to 1 micron, although lesser and greater first periodicities may also be used. The second periodicity may be in a range from 10 nm to 1 micron, although lesser and greater first periodicities may also be used. The second periodicity may be the same as, or may be different from, the first periodicity. The lateral dimension of each pillar of a magnetic tunnel junction 150 (such as a diameter, major axis, a minor axis, or a lateral distance between a parallel pair of sidewalls) may be in a range from 10% to 95%, such as from 30% to 80%, of the first periodicity and/or of the second periodicity.

In one embodiment, each magnetic tunnel junction 150 selected from the plurality of arrays of magnetic tunnel junctions 150 may include a spin-orbit torque (SOT) magnetic tunnel junction (140, 146, 148, 160). In this embodiment, each SOT magnetic tunnel junction (140, 146, 148, 160) may include a spin-orbit torque (SOT) transfer layer 160 in contact with the free magnetization layer 148. In one embodiment, within each of the SOT magnetic tunnel junctions (140, 146, 148, 160), the reference magnetization layer 140, the nonmagnetic tunnel barrier layer 146, and the free magnetization layer 148 may be arranged along a vertical direction, and the SOT transfer layer 160 contacts at least one sidewall of the free magnetization layer 148.

Generally, each SOT transfer layer 160 may be configured to allow flow of electrical current along a direction that is parallel to at least one interface with a respective free magnetization layer 148. In one embodiment, each SOT transfer layer 160 may laterally surround, and may contact, a respective free magnetization layer 148. In this embodiment, the preferred directions of magnetization of the free magnetization layer 148 may be parallel to the at least one interface between the free magnetization layer 148 and the SOT transfer layer 160. The electrical current through each SOT transfer layer 160 may be controlled by a respective control circuit, and may flow in two opposite directions to enable programming of the magnetization direction of the free magnetization layer 148 along a parallel direction (i.e., a direction that is parallel to the magnetization direction of the reference magnetization layer 140 in a same SOT magnetic tunnel junction (140, 146, 148, 160)) or along an antiparallel direction (i.e., a direction that is antiparallel to the magnetization direction of the reference magnetization layer 140 in the same SOT magnetic tunnel junction (140, 146, 148, 160)). While FIG. 1C illustrates a configuration in which an SOT transfer layer 160 contacts two sidewalls of a free magnetization layer 148 along a current flow direction, embodiments are expressly contemplated herein in which the interface between the SOT transfer layer 160 and the free magnetization layer 148 is curved, or multiple interfaces are provided between the SOT transfer layer 160 and the free magnetization layer 148.

Generally, the SOT transfer layers 160 for an array of magnetic tunnel junctions 150 may be formed after formation of an array of pillar structures including a respective vertical stack of a free magnetization layer 148, a nonmagnetic tunnel barrier layer 146, and a reference magnetization layer 140, by depositing a dielectric spacer material layer having a top surface in contact with sidewalls of the free magnetization layers 148, and by depositing and patterning a metal layer such that patterned portions of the metal layer constitute the SOT transfer layers 160. Generally, the SOT transfer layers 160 comprises, and/or consists essentially of, at least one elemental metal having a high atomic number, such as an atomic number in a range from 72 to 78. In one embodiment, the SOT transfer layers 160 comprises, and/or consists essentially of tungsten or rhenium. Alternatively, light metals may be doped with heavy-metal atoms. The spin Hall effect of Cu-based alloys including CuBi,91 CuPb,91 Culr,92 CuPt,93 and CuAu94 have been intensively studied. Notably, Cu99.5Bi0.591 shows a large SHA of 0.24, which is larger than the SHA measured in heavy metals such as Pt and Ta. Han et al., Spin-orbit torques: Materials, physics, and devices, Appl. Phys. Lett. 118, 120502 (2021) describes use of such alloys as materials for an SOT transfer layer. Subsequently, a dielectric material may be deposited over the array of pillar structures and over the SOT transfer layers 160, and may be planarized to provide a planar top surface on which a filament-forming dielectric material layer 100 may be subsequently formed.

In one embodiment, the stack of a plurality of arrays of magnetic tunnel junctions 150 comprises three or more arrays of magnetic tunnel junctions 150, and the at least one filament-forming dielectric material layer 100 comprises two or more filament-forming dielectric material layers 100.

In one embodiment, an array of magnetic tunnel junctions 150 may contact a top surface of an underlying filament-forming dielectric material layer 100, and may contact a bottom surface of an overlying filament-forming dielectric material layer 100. Alternatively, nonmagnetic metallic material portions (not illustrated) may be inserted between an array of magnetic tunnel junctions 150 and an underlying filament-forming dielectric material layer 100, and/or between an array of magnetic tunnel junctions 150 and an overlying filament-forming dielectric material layer 100. Such nonmagnetic metallic material portions may comprise metallic seed layers, bottom-side connection electrode, or top-side connection electrodes.

In one embodiment, a vertically neighboring pair of a first array of magnetic tunnel junctions 150 and a second array of magnetic tunnel junctions 150 may be spaced apart along the stack direction, and may have an areal overlap in a plan view along the stack direction. A plan view refers a view in which lateral extents of various elements along directions perpendicular to the stack direction are illustrated. In one embodiment, arrays of magnetic tunnel junctions 150 may be aligned such that each array of magnetic tunnel junctions 150 occupy a same area in the plan view.

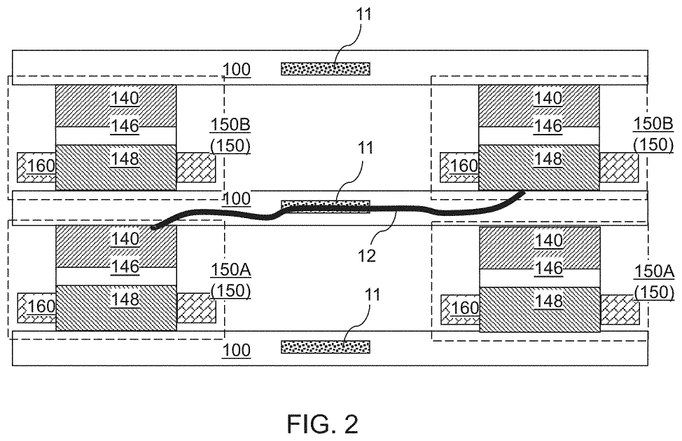

Referring to FIG. 2, a portion of an alternative embodiment of the first exemplary structure is illustrated, which may be derived from the first exemplary structure by forming conductive bridge elements 11 within the filament-forming dielectric material layers 100. In one embodiment, at least a subset of the conductive bridge elements 11 may be formed as an array of discrete conductive bridge elements having a same periodicity as an overlying array of magnetic tunnel junctions 150 or as an underlying array of magnetic tunnel junctions 150. In one embodiment, the conductive bridge elements 11 may include rectangular arrays of discrete conductive bridge elements or hexagonal arrays of discrete conductive bridge elements. Alternatively or additionally, at least a subset of the conductive bridge elements 11 may be formed as a grid or a mesh of interconnected conductive bridge elements. Generally, the conductive bridge elements 11 may be formed midway between neighboring pairs of magnetic tunnel junctions within a respective one of the filament-forming dielectric material layers 100.

The conductive bridge elements 11 facilitate formation of filamentary connections 12 between neighboring pairs of magnetic tunnel junctions 150 during programming. In one embodiment, the conductive bridge elements 11 may comprise doped portions of the filament-forming dielectric material layers 100 that locally exhibit metallic conductive properties. In this embodiment, the dopants within the conductive bridge elements 11 may comprise any of the non-magnetic transition metals. In this embodiment, the metal-to-oxygen ratio in the conductive bridge elements may be in a range from 1:1 to 10:1, whereas metal-to-oxygen ratio in the undoped portions of the filament-forming dielectric material layer 100 may be about 1:2 (for example, in embodiments in which the filament-forming dielectric material layer 100 consists essentially of HfO₂). In one embodiment, the conductive bridge elements 11 may comprise a metallic seed mesh that supports lateral filamentary growth. In one embodiment, the conductive bridge elements 11 may be include metal-doped regions within the filament-forming dielectric material layers 100. The thickness of the conductive bridge elements 11 may be in a range from a monolayer to 100% of the thickness of the filament-forming dielectric material layers 100. In an alternative embodiment, the conductive bridge elements 11 may be formed as metallic coating portions on a top surface or on a bottom surface of a respective one of the filament-forming dielectric material layers 100. FIG. 2 illustrates an exemplary filamentary connection 12 that passes through one of the conductive bridge elements 11.

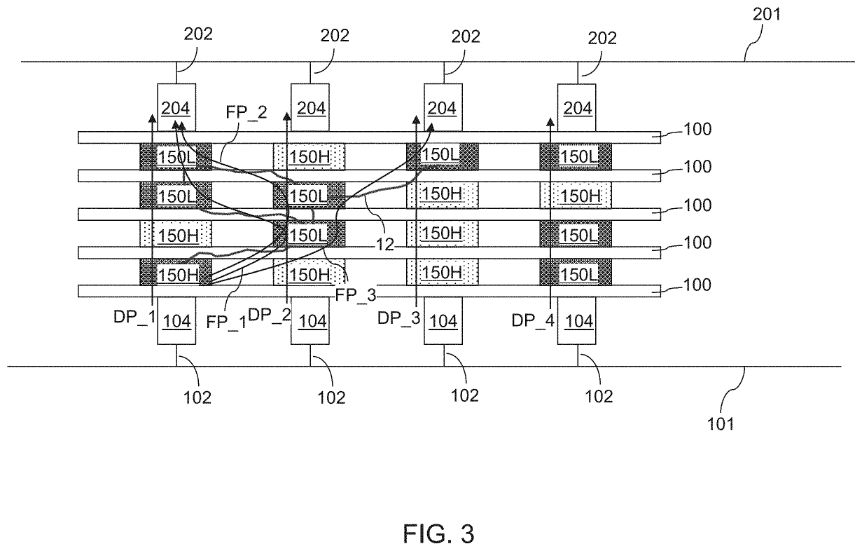

FIG. 3 illustrates an exemplary configuration of the first exemplary structure after formation of filamentary connections 12. Generally, the network computation device may include the first exemplary structure, which includes a first set of input/output nodes (102, 202) electrically connected to bottom ends of magnetic tunnel junctions 150 within a bottommost array of magnetic tunnel junctions 150 selected from the plurality of magnetic tunnel junctions 150; and a second set of input/output nodes (102, 202) electrically connected to top end of magnetic tunnel junctions 150 within a topmost array of magnetic tunnel junctions 150 selected from the plurality of magnetic tunnel junctions 150. One of the first set and the second set comprises input nodes 102, and another of the first set and the second set comprises output nodes 202. In one embodiment, a filamentary connection 12 may laterally extend from a metallic material of a reference magnetization layer 140 in a magnetic tunnel junction 150 having a low resistance state and located within an array of first magnetic tunnel junctions 150A to a metallic material of a free magnetization layer 148 in a magnetic tunnel junction 150 having a low resistance state and located within an array of second magnetic tunnel junctions 150B that is located above, or below, the array of first magnetic tunnel junctions 150A.

While FIG. 3 illustrates an embodiment in which the input nodes 102 are provided at the bottom and the output nodes 202 are provided at the top, embodiments are expressly contemplated herein in which the input nodes 102 are provided at the top and the output nodes 202 are provided at the bottom. Further, it is understood that each array of magnetic tunnel junctions 150 may be provided as a two-dimensional array of magnetic tunnel junctions 150, the input nodes 102 may be provided as a two-dimensional array of input nodes 102, and the output nodes 202 may be provided as a two-dimensional array of output nodes 202.

The input nodes 102 may be grouped into at least one set of interconnected input nodes 101, which may comprise a plurality of sets of interconnected input nodes 101 or a single set of interconnected input nodes 101. Likewise, the output nodes 202 may be grouped into at least one set of interconnected output nodes 201, which may comprise a plurality of sets of interconnected output nodes 201 or a single set of interconnected output nodes 201. While the present disclosure is described using an embodiment using a single set of interconnected input nodes 101 and a single set of interconnected output nodes 201, embodiments are expressly contemplated herein in which multiple sets of interconnected input nodes 101 and/or multiple set of interconnected output nodes 201 are used. Further, embodiments are expressly contemplated herein in which each of the input nodes 102 and/or the output nodes 202 is addressed independently, i.e., function as independent electrical nodes.

In one embodiment, the network computation device includes the first exemplary structure (or alternative embodiments thereof), which may include an array of passive elements (104, 204) located between the first set of input/output nodes (such as the input nodes 102) and the bottom ends of magnetic tunnel junctions 150 within the bottommost array of magnetic tunnel junctions 150, or between the second set of input/output nodes (such as the output nodes 202) and the top ends of magnetic tunnel junctions 150 within the topmost array of magnetic tunnel junctions 150. In one embodiment, an array of input-side passive elements 104 may be provided between the input nodes 102 and a first array of magnetic tunnel junctions 150 (such as the bottommost array of magnetic tunnel junctions 150), and an array of output-side passive elements 204 may be provided between the output nodes 202 and a second array of magnetic tunnel junctions 150 (such as the topmost array of magnetic tunnel junctions 150).

Generally, a network computation device of the present disclosure may be provided, which may include a stack of a plurality of arrays of magnetic tunnel junctions 150 interlaced with at least one filament-forming dielectric material layer 100. At least a subset of magnetic tunnel junctions 150 within the plurality of arrays of magnetic tunnel junctions 150 may be programmed into a respective programmed state selected from a parallel state and an antiparallel state. In one embodiment, each magnetic tunnel junctions 150 within the plurality of arrays of magnetic tunnel junctions 150 may be programmed into a respective programmed state. This step is herein referred to as a weight assignment step.

In one embodiment, the plurality of arrays of magnetic tunnel junctions 150 may include a plurality of arrays of spin-orbit torque (SOT) magnetic tunnel junctions. In this embodiment, programming of the subset of magnetic tunnel junctions 150 within the plurality of arrays of magnetic tunnel junctions 150 may be performed by transfer of spin-orbit torque to a free magnetization layer 148 within a respective SOT magnetic tunnel junction from a spin-orbit torque transfer layer 160 that contacts the free magnetization layer 148 within the respective SOT magnetic tunnel junction.

Programming of the magnetic tunnel junctions 150 corresponds to a weight-assigning operation in preparation of a network-based computing. Each magnetic tunnel junction 150 that is programmed into a parallel state has a low electrical resistance, and thus, has high electrical conductance. Each magnetic tunnel junction 150 that is programmed into an antiparallel state has a high electrical resistance, and thus, has low electrical conductance. Portions of the filament-forming dielectric material layers 100 located between a low-resistance magnetic tunnel junction 150L within an array of magnetic tunnel junctions 150 and another low-resistance magnetic tunnel junction 150L within an immediately overlying array of magnetic tunnel junctions 150 or within an immediately underlying array of magnetic tunnel junctions 150 are conducive to formation of a filamentary connection 12 therein. In contrast, portions of the filament-forming dielectric material layers 100 located adjacent to a high-resistance magnetic tunnel junction 150H are not conducive to formation of a filamentary connection 12 therein.

According to an embodiment of the present disclosure, the weight assignment step may be followed by a filament formation step, in which voltage pulses may be applied across the input nodes 102 and the output nodes 202 to form filamentary connections 12 within the filament-forming dielectric material layers 100. For example, a respective programming electrical voltage bias of a first polarity may be applied across at least one programming access point pairs, which includes an input node 102 and an output node 202. In one embodiment, each programming access point pair may include a respective first programming access point electrically connected to a bottom end of a respective magnetic tunnel junction 150 within the bottommost array of magnetic tunnel junctions 150, and a second programming access point electrically connected to a top end of a respective magnetic tunnel junction 150 within the topmost array of magnetic tunnel junctions 150. In the illustrated example, each first programming access point may include an input node 102 or a set of interconnected input nodes 102, and each second programming access point may comprise an output node 202 or a set of interconnected output nodes 202. At least one filamentary connection 12 (including a conductive filament with reduced density of oxygen vacancies) may be formed in a respective one of the at least one filament-forming dielectric material layer 100. Electrical conductively increases in each region in which the at least one filamentary connection 12 is formed. In some embodiment, the conductive path formation step can include various programming schemes. In some embodiments, a programming voltage may be applied across interconnected sets input nodes 102 and interconnected sets of output nodes 202. In one embodiment, a programming voltage may be applied across an interconnected set of all input nodes 102 and an interconnected set of all output nodes 202. In some other embodiments, programming voltages may be applied across individual pairs of an input node 102 and an output node 202. In some embodiments, sets of input nodes 102 and/or sets of output nodes 202 may be interconnected, or “primed,” before the programming operation. During subsequent reset operations, the same node grouping scheme may be used to effectively remove the filamentary connections 12 in the at least one filament-forming dielectric material layer 100.

A contiguous set of filamentary connections 12 and low-resistance magnetic tunnel junctions 150L (i.e., magnetic tunnel junctions 150 that are programmed into parallel states) between an input node 102 (or an input-side passive element 104) and an output node 202 (or an output-side passive element 204) constitutes a filamentary conductive path (FP_1, FP_2, FP_3). Three filamentary conductive paths (FP_1, FP_2, FP_3) are illustrated in FIG. 3. The pattern of the filamentary conductive paths (FP_1, FP_2, FP_3) is a function of the spatial arrangement of the low-resistance magnetic tunnel junctions 150L, and is a function of an applied external voltage pattern that is used during a programming operation to form the filamentary conductive paths (FP_1, FP_2, FP_3).

A vertical stack of magnetic tunnel junctions 150 having an areal overlap in a plan view and extending between an input node 102 (or an input-side passive element 104) and an output node 202 (or an output-side passive element 204) having an areal overlap with the input node 102 in the plan view constitutes a direct conductive path (DP_1, DP2, DP_3, DP_4). The conductance of each direct conductive path (DP_1, DP2, DP_3, DP_4) is function of the programmed state of the magnetic tunnel junctions 150 therein. The higher the total number of low-resistance magnetic tunnel junctions 150L within each direct conductive path (DP_1, DP2, DP_3, DP_4), the higher the conductance of the respective direct conductive path (DP_1, DP2, DP_3, DP_4). The higher the total number of high-resistance magnetic tunnel junctions 150H within each direct conductive path (DP_1, DP2, DP_3, DP_4), the lower the conductance of the respective direct conductive path (DP_1, DP2, DP_3, DP_4). Thus, a direct conductive path (DP_1, DP2, DP_3, DP_4) does not necessary have a higher conductance than a filamentary conductive path (FP_1, FP_2, FP_3), but the conductance of each direct conductive path (DP_1, DP2, DP_3, DP_4) may be higher or lower than the conductance of a filamentary conductive path (FP_1, FP_2, FP_3).

In one embodiment, the effect of the formation of the filamentary connections 12 may be quantified, and a solution to the network computation problem may be generated, by determining the magnitude of electrical current between a first measurement access point electrically connected to a bottom end of a magnetic tunnel junction 150 within a bottommost array of magnetic tunnel junctions 150 selected from the plurality of arrays of magnetic tunnel junctions 150 and a second measurement access point electrically connected to a top end of a magnetic tunnel junction 150 within a topmost array of magnetic tunnel junctions 150 selected from the plurality of arrays of magnetic tunnel junctions 150. In the illustrated example, the first measurement access point may be an input node 102 or a set of interconnected input nodes 102, and each second measurement access point may comprise an output node 202 or a set of interconnected output nodes 202.

Generally, reconfigurable interconnects may be generated in the form of filamentary connections 12 by providing a programming voltage bias between vertically neighboring arrays of magnetic tunnel junctions. The filamentary connections 12 may be formed within portions of the filament-forming dielectric material layers 100 that are located between a neighboring pair of low-resistance magnetic tunnel junctions 150L located at different levels, i.e., between a low-resistance magnetic tunnel junction 150L located in an underlying array of magnetic tunnel junctions 150 and a low-resistance magnetic tunnel junction 150L located in an overlying array of magnetic tunnel junctions 150 and arranged as a laterally-neighboring pair of magnetic tunnel junctions 150 in a plan view.

The network computation device of the present disclosure may emulate neuromorphic computing. In this embodiment, each binary neuron in a neuromorphic computing problem may include a magnetic tunnel junction 150 that may be programmed into a low-resistance state or into a high-resistance state, and formation of synapses between neighboring neurons is emulated by formation of filamentary connections 12 between neighboring pairs of neurons in low-resistance states. Synaptic connection of different strengths may be emulated by application of different programming bias voltages between a respective programming access point pair (such as an input node 102 and an output node 202).

The network computation device of the present disclosure may be partially or fully reset to remove a subset of the filamentary connections 12 or the entirety of the filamentary connections 12. An electrical current flowing in an opposite direction may be flowed between a reset access point pair, which may be a respective pair of an input node 102 and an output node 202. The filamentary connections 12 may be erased step by step in stages, and the network computation device of the present disclosure may be fully reset for use in solving a different neuromorphic computation problem.

In one embodiment, the reset operation may be performed in an analog mode, in which the reverse current is used as a backpropagation feedback for training purposes.

Generally, the reset operation may include the step of applying a respective reset electrical voltage bias of a second polarity across at least one reset access point pairs. The second polarity is an opposite of the first conductivity type. Each reset access point pair comprises a respective first reset access point (such as an input node 102) electrically connected to a bottom end of a respective magnetic tunnel junction 150 within the bottommost array of magnetic tunnel junctions 150, and a second reset access point (such as an output node 202) electrically connected to a top end of a respective magnetic tunnel junction 150 within the topmost array of magnetic tunnel junctions 150. One or more of the at least one filamentary connection 12 may be removed by application of the respective reset electrical voltage bias.

Generally, the filament-forming dielectric material layers 100 of the network computation device of the present disclosure enable formation of filamentary connections 12 to provide variable and reconfigurable interconnects between magnetic tunnel junctions 150 that emulate binary neurons. The synaptic weights between neurons may be encoded into the network computation device of the present disclosure through formation of filamentary connections 12 having different values of electrical conductance. In some embodiments, electrical current that is forced through the vertical stack of the arrays of magnetic tunnel junctions 150 and the at least one filament-forming dielectric material layer 100 induces formation of filamentary connections between adject levels of magnetic tunnel junctions 150. The encoded weights may be transferred into the network computation device of the present disclosure for inference.

In one embodiment, repeated application of programming voltages may strengthen pre-existing electrically conductive paths within the network computation device of the present disclosure, which emulates a neuromorphic learning process. Upon development of the electrically conductive paths with repeated reinforcement of electrically conductive paths, the network computation device of the present disclosure allows inference of a final solution to the neuromorphic computation problem. The solution may be generated by measuring electrical resistance between pairs of input nodes 102 and output nodes 202 (for example, through measurement of electrical current therebetween under a voltage bias condition).

In an illustrative example for the configuration of FIG. 3, for a set of interconnected input nodes 101 that is provided with an input X a set of interconnected output nodes 202 from which an output Y is to be measured, the output Y may be proportional to X and to the sum of all conductance values of the electrically conductive paths between the set of interconnected input nodes 101 and the set of interconnected output nodes 202. If the filamentary conductive paths (FP_1, FP_2, FP_3) have respective electrical conductance values of C(FP_1), C(FP_2), and C(FP_3), and if the direct conductive paths (DP_1, DP2, DP_3, DP_4) have a respective electrical conductance values of C(DP_1), C(DP_2), C(DP_3), and C(DP_4), the sum of all conductive values of the electrically conductive paths between the set of interconnected input nodes 101 and the set of interconnected output nodes 202 may be given by the sum of C(FP_1), C(FP_2), C(FP_3), C(DP_1), C(DP_2), C(DP_3), and C(DP_4). In other words, Y is proportional to X times {C(FP_1)+C(FP_2)+C(FP_3)+C(DP_1)+C(DP_2)+C(DP_3)+C(DP_4)}. As discussed above, the electrical conductance values of C(DP_1), C(DP_2), C(DP_3), and C(DP_4) depend on the programed state of the magnetic tunnel junctions within the respective direct conductive path (DP_1, DP2, DP_3, DP_4). The electrical conductance values of C(FP_1), C(FP_2), and C(FP_3) depend not only on the programed state of the magnetic tunnel junctions within the respective filamentary conductive path (FP_1, FP_2, FP_3) but also on the electrical conductance of the filamentary connections 12 within the respective filamentary conductive path (FP_1, FP_2, FP_3).

While the first exemplary structure includes a fully parallelized (i.e., non-staggered) configuration in which each of magnetic tunnel junction 150 has a full areal overlap with any underlying array of magnetic tunnel junctions 150 and with any overlying arrays of magnetic tunnel junctions 150, the network computation device of the present disclosure may be implemented in a non-parallelized configuration, i.e., in a staggered configuration.

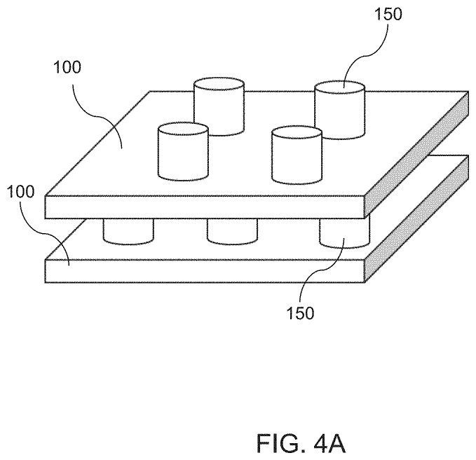

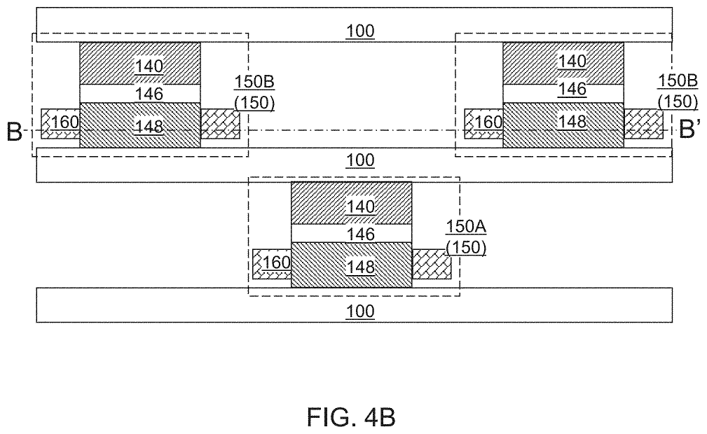

Referring to FIGS. 4A-4C, a second exemplary structure may be derived from the first exemplary structure (or any of the alternative embodiments thereof) by staggering the arrays of magnetic tunnel junctions 150 in a plan view. In this embodiment, each vertically neighboring pair of arrays of magnetic tunnel junctions may be laterally offset along the first horizontal direction by one-half of the first periodicity (i.e., the periodicity along the first horizontal direction), and/or may be laterally offset along the second horizontal direction by one-half of the second periodicity (i.e., the periodicity along the second horizontal direction). The second horizontal direction may, or may not, be perpendicular to the first horizontal direction.

In one embodiment, a vertically neighboring pair of a first array of magnetic tunnel junctions 150 and a second array of magnetic tunnel junctions 150 are laterally offset from each other in a plan view (which is a view along the stack direction such as the vertical direction). In one embodiment, the first array of magnetic tunnel junctions 150 may contact a bottom surface of a filament-forming dielectric material layer 100, and the second array of magnetic tunnel junctions 150 may contact a top surface of the filament-forming dielectric material layer 100. In another embodiment, the first array of magnetic tunnel junctions 150 may contact a top surface of a filament-forming dielectric material layer 100, and the second array of magnetic tunnel junctions 150 may contact a bottom surface of the filament-forming dielectric material layer 100.

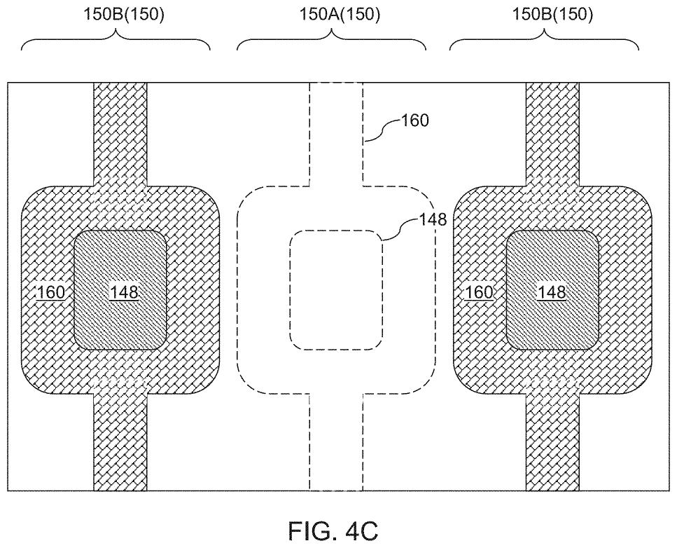

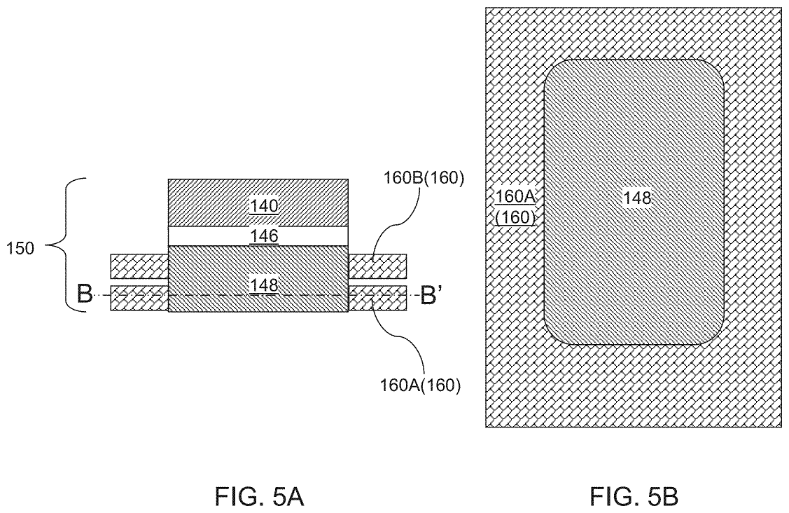

Referring to FIGS. 5A and 5B, a first alternative embodiment of a magnetic tunnel junction 150 according to an embodiment of the present disclosure is illustrated. Each magnetic tunnel junction 150 comprises a pillar structure that contains a reference magnetization layer 140, a nonmagnetic tunnel barrier layer 146, and a free magnetization layer 148 that are arranged along a vertical direction. A plurality of SOT transfer layers 160 may be provided within each magnetic tunnel junction 150. In one embodiment, the plurality of SOT transfer layers 160 may comprise a first SOT transfer layer 160A contacting a lower portion of at least one sidewall of the free magnetization layer 148, and a second SOT transfer layer 160B contacting an upper portion of the at least one sidewall of the free magnetization layer 148. Generally, each of the plurality of SOT transfer layers (160A, 160B) may be formed by depositing and patterning a respective metal layer such that a sidewall of the respective metal layer contacts a respective portion of a sidewall of the respective free magnetization layer 148. Laterally-extending SOT transfer layers (160A, 160B) may force magnetization on the free magnetization layer 148 of a respective magnetic tunnel junction 150. Each of the SOT transfer layers (160A, 160B) may be electrically connected to a respective driver circuit (not illustrated) through a respective set of metal interconnect structures (not illustrated).

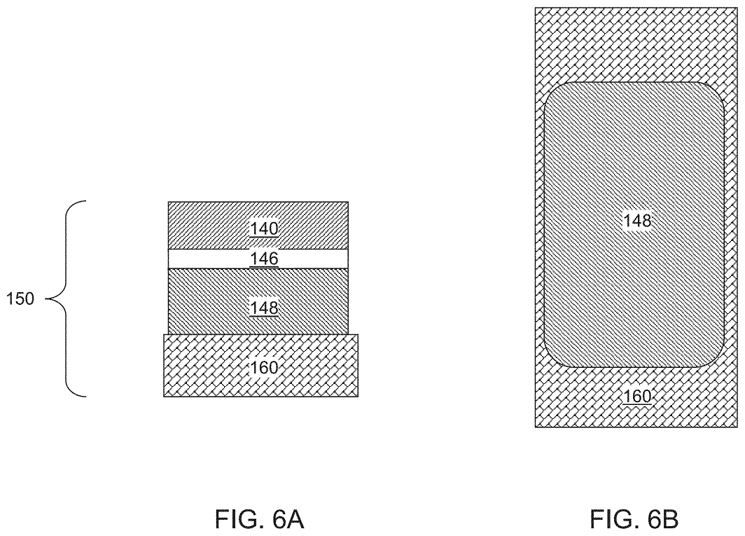

Referring to FIGS. 6A and 6B, a second alternative embodiment of a magnetic tunnel junction 150 according to an embodiment of the present disclosure is illustrated. Each magnetic tunnel junction 150 comprises a pillar structure that contains a reference magnetization layer 140, a nonmagnetic tunnel barrier layer 146, and a free magnetization layer 148 that are arranged along a vertical direction. An SOT transfer layer 160 contacts a bottom surface or a top surface of the free magnetization layer 148. In this embodiment, the interface between the SOT transfer layer 160 and the free magnetization layer 148 is parallel to the interface between the free magnetization layer 148 and the nonmagnetic tunnel barrier layer 146. The SOT transfer layer 160 may comprises a pair of tabs that laterally protrude away from sidewalls of the free magnetization layer 148. The pair of tabs may be used to provide electrical connection to metal interconnect structures (not shown). In one embodiment, the metal interconnect structures may comprise a pair of metal vias.

In this embodiment, the respective SOT transfer layer 160 may be formed by depositing a metal layer such that the metal layer contacts a bottom surface or a top surface of a respective free magnetization material layer, and by patterning the metal layer such that the metal layer comprises laterally protruding portions that laterally protrude from a sidewall of the respective free magnetization layer 148 (which is a patterned portion of the respective free magnetization material layer). The SOT transfer layer 160 may function as a magnetization line and as a conductive reservoir for a filament-forming dielectric material layer 100 that functions in a manner similar to the conductive bridge elements 11 described above.

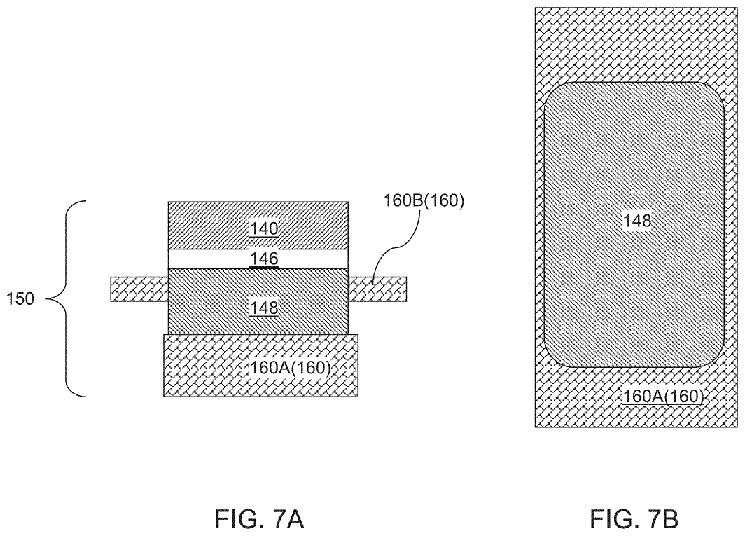

Referring to FIGS. 7A and 7B, a third alternative embodiment of a magnetic tunnel junction according to an embodiment of the present disclosure is illustrated. Each magnetic tunnel junction 150 comprises a pillar structure that contains a reference magnetization layer 140, a nonmagnetic tunnel barrier layer 146, and a free magnetization layer 148 that are arranged along a vertical direction. A first SOT transfer layer 160A may be formed on a bottom surface or a top surface of the free magnetization layer 148, and a second SOT transfer layer 160B may be formed on at least one sidewall of the free magnetization layer 148 within each of the magnetic tunnel junctions 150. A combination of the patterning method of FIGS. 5A and 5B and the patterning method of FIGS. 6A and 6B may be used to provide a combination of the first SOT transfer layer 160A and the second SOT transfer layer 160B of FIGS. 7A and 7B.

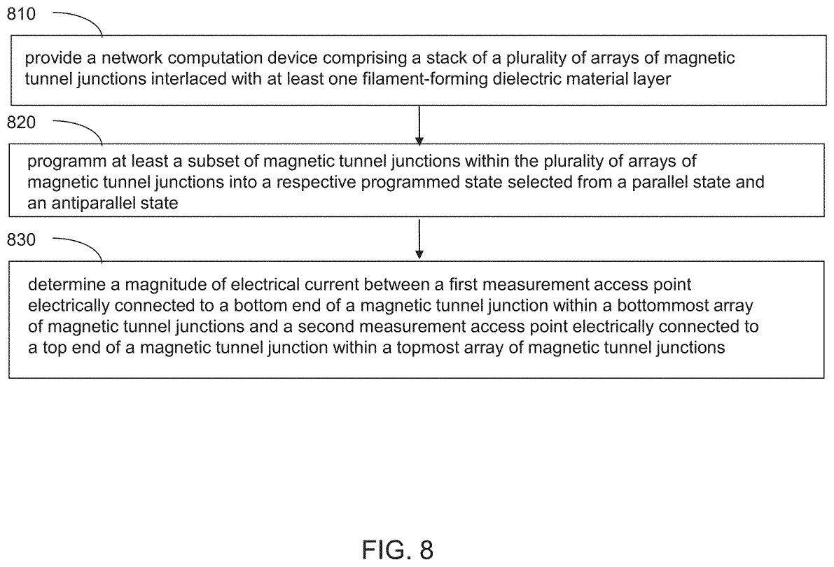

Referring to FIG. 8, a flowchart illustrates the general processing steps for operating a network computation device according to an embodiment of the present disclosure.

Referring collectively to FIGS. 1A-7B and step 810, a network computation device comprising a stack of a plurality of arrays of magnetic tunnel junctions 150 interlaced with at least one filament-forming dielectric material layer 100 is provided.

Referring collectively to FIGS. 1A-7B and step 820, at least a subset of magnetic tunnel junctions 150 within the plurality of arrays of magnetic tunnel junctions 150 is programmed into a respective programmed state selected from a parallel state and an antiparallel state.

Referring collectively to FIGS. 1A-7B and step 830, a magnitude of electrical current is determined (by measurement) between a first measurement access point (such as an input node 102) electrically connected to a bottom end of a magnetic tunnel junction 150 within a bottommost array of magnetic tunnel junctions 150 selected from the plurality of arrays of magnetic tunnel junctions 150 and a second measurement access point (such as an output node 202) electrically connected to a top end of a magnetic tunnel junction 150 within a topmost array of magnetic tunnel junctions 150 selected from the plurality of arrays of magnetic tunnel junctions 150.

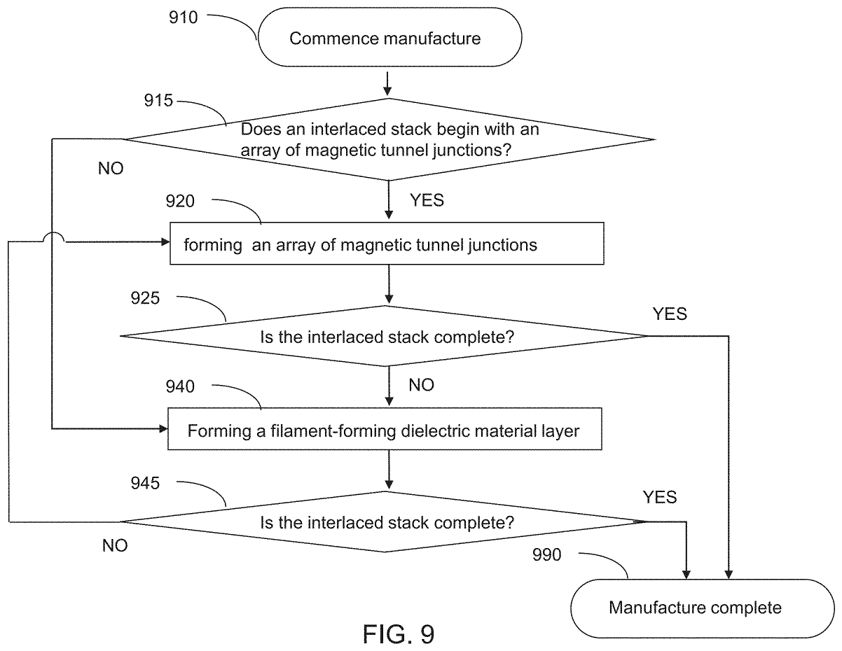

Referring to FIG. 9, a flowchart illustrates the general processing steps for manufacturing a network computation device according to an embodiment of the present disclosure.

Referring to step 910, manufacture of a network computation device of the present disclosure commences.

Referring to step 915, a beginning layer of an interlaced stack of a plurality of arrays of magnetic tunnel junctions 150 interlaced with at least one filament-forming dielectric material layer 100 within the network computation device of the present disclosure is identified. If the beginning layer comprises an array of magnetic tunnel junctions 150, the process flow proceeds to step 920. If the beginning layer comprises a filament-forming dielectric material layer 100, the process flow proceeds to step 940.

At step 920, an array of magnetic tunnel junctions 150 may be formed by depositing and patterning various material layers. A dielectric material layer is subsequently deposited and planarized to provide a planar top surface for the dielectric material layer that is coplanar with the top surfaces of the array of magnetic tunnel junctions 150.

At step 925, whether the interlaced stack is complete is determined. As discussed above, the interlaced stack comprises a plurality of arrays of magnetic tunnel junctions 150 interlaced with at least one filament-forming dielectric material layer 100. If the interlaced stack is not complete, the process flow proceeds to step 940. If the interlaced stack is complete, the process flow proceeds to step 990, and manufacture of the interlaced stack is complete.

At step 940, a filament-forming dielectric material layer 100 is deposited.

At step 945, whether the interlaced stack is complete is determined. If the interlaced stack is not complete, the process flow proceeds to step 920. If the interlaced stack is complete, the process flow proceeds to step 990, and manufacture of the interlaced stack is complete.

The network computation device of the present disclosure may include a monolithic three-dimensional structure that is formed using semiconductor manufacturing processes known in the art. The network computation device of the present disclosure is highly scalable. Each layer of an array of magnetic tunnel junctions 150 and a filament-forming dielectric material layer 100 adds an additional computational stage along the stack direction, and allows direct mapping of a hidden layer in an artificial neural network.

The monolithic three-dimensional structure of the network computation device of the present disclosure potentially allows no-latency inference (i.e., immediate inference) and a much reduced, if not entirely eliminated, need of weight refresh. The reconfigurable interconnects allow for increased inference efficiency and much reduced weight redundancy. The network computation device of the present disclosure intrinsically favors analog solutions with on-chip training. For example, filaments strength may be strengthened/weakened depending on states of the neighboring magnetic tunnel junctions 150 and current directions. Thus, power consumption for digital-to-analog conversion and/or analog-to-digital conversion for network computation may be minimized during operation of the network computation device of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A network computation device comprising:
a stack of a plurality of arrays of magnetic tunnel junctions that are spaced apart along a stack direction; and
at least one filament-forming dielectric material layer located between each vertically neighboring pair of arrays of magnetic tunnel junctions selected from the plurality of magnetic tunnel junctions.

2. The network computation device of claim 1, wherein each of the at least one filament-forming dielectric material layer comprises a dielectric material that forms conductive filaments therein upon application of an electrical bias thereacross.

3. The network computation device of claim 2, wherein each of the at least one filament-forming dielectric material layer comprises hafnium oxide.

4. The network computation device of claim 1, wherein each magnetic tunnel junction selected from the plurality of arrays of magnetic tunnel junctions comprises a reference magnetization layer, a nonmagnetic tunnel barrier layer, and a free magnetization layer having two preferred magnetization directions that are parallel or antiparallel to a fixed magnetization direction of the reference magnetization layer.

5. The network computation device of claim 4, wherein each magnetic tunnel junction selected from the plurality of arrays of magnetic tunnel junctions comprises a spin-orbit torque (SOT) transfer layer in contact with the free magnetization layer.

6. The network computation device of claim 5, wherein:
the reference magnetization layer, the nonmagnetic tunnel barrier layer, and the free magnetization layer are arranged along a vertical direction; and
the SOT transfer layer contacts at least one sidewall of the free magnetization layer.

7. The network computation device of claim 5, wherein:
the reference magnetization layer, the nonmagnetic tunnel barrier layer, and the free magnetization layer are arranged along a vertical direction; and
the SOT transfer layer contacts a bottom surface or a top surface of the free magnetization layer and comprises a pair of tabs that laterally protrude away from sidewalls of the free magnetization layer.

8. The network computation device of claim 1, wherein:
the stack of a plurality of arrays of magnetic tunnel junctions comprises three or more arrays of magnetic tunnel junctions; and
the at least one filament-forming dielectric material layer comprises two or more filament-forming dielectric material layers.

9. The network computation device of claim 1, wherein a vertically neighboring pair of a first array of magnetic tunnel junctions and a second array of magnetic tunnel junctions has an areal overlap in a plan view.

10. The network computation device of claim 1, wherein a vertically neighboring pair of a first array of magnetic tunnel junctions and a second array of magnetic tunnel junctions are laterally offset from each other in a plan view.

11. The network computation device of claim 1, further comprising:
a first set of input/output nodes electrically connected to bottom ends of magnetic tunnel junctions within a bottommost array of magnetic tunnel junctions selected from the plurality of magnetic tunnel junctions; and
a second set of input/output nodes electrically connected to top end of magnetic tunnel junctions within a topmost array of magnetic tunnel junctions selected from the plurality of magnetic tunnel junctions,
wherein one of the first set and the second set comprises input nodes, and another of the first set and the second set comprises output nodes.

12. The network computation device of claim 11, further comprising an array of passive elements located between the first set of input/output nodes and the bottom ends of magnetic tunnel junctions within the bottommost array of magnetic tunnel junctions, or between the second set of input/output nodes and the top ends of magnetic tunnel junctions within the topmost array of magnetic tunnel junctions.

13. A method of operating a network computation device, comprising:
providing a network computation device comprising a stack of a plurality of arrays of magnetic tunnel junctions interlaced with at least one filament-forming dielectric material layer;
programming at least a subset of magnetic tunnel junctions within the plurality of arrays of magnetic tunnel junctions into a respective programmed state selected from a parallel state and an antiparallel state; and
determining a magnitude of electrical current between a first measurement access point electrically connected to a bottom end of a magnetic tunnel junction within a bottommost array of magnetic tunnel junctions selected from the plurality of arrays of magnetic tunnel junctions and a second measurement access point electrically connected to a top end of a magnetic tunnel junction within a topmost array of magnetic tunnel junctions selected from the plurality of arrays of magnetic tunnel junctions.

14. The method of claim 13, wherein:
the plurality of arrays of magnetic tunnel junctions comprises a plurality of arrays of spin-orbit torque (SOT) magnetic tunnel junctions; and
programming of the subset of magnetic tunnel junctions within the plurality of arrays of magnetic tunnel junctions is performed by transfer of spin-orbit torque to a free magnetization layer within a respective SOT magnetic tunnel junction from a spin-orbit torque transfer layer that contacts the free magnetization layer within the respective SOT magnetic tunnel junction.

15. The method of claim 13, further comprising applying a respective programming electrical voltage bias of a first polarity across at least one programming access point pairs, wherein:
each programming access point pair comprises a respective first programming access point electrically connected to a bottom end of a respective magnetic tunnel junction within the bottommost array of magnetic tunnel junctions and a second programming access point electrically connected to a top end of a respective magnetic tunnel junction within the topmost array of magnetic tunnel junctions; and
at least one filamentary connection is formed in a respective one of the at least one filament-forming dielectric material layer, and electrical conductively increases in each region in which the at least one filamentary connection is formed.

16. The method of claim 15, further comprising applying a respective reset electrical voltage bias of a second polarity across at least one reset access point pairs, wherein:
the second polarity is an opposite of the first conductivity type;
each reset access point pair comprises a respective first reset access point electrically connected to a bottom end of a respective magnetic tunnel junction within the bottommost array of magnetic tunnel junctions and a second reset access point electrically connected to a top end of a respective magnetic tunnel junction within the topmost array of magnetic tunnel junctions; and
one or more of the at least one filamentary connection is removed by application of the respective reset electrical voltage bias.

17. A method of forming a network computation device, comprising:
forming an interlaced stack of a plurality of arrays of magnetic tunnel junctions and at least one filament-forming dielectric material layer along a vertical direction, wherein:
each array of arrays of magnetic tunnel junctions selected from the plurality of arrays of magnetic tunnel junctions is formed by depositing and patterning a layer stack including a reference magnetization material layer, a nonmagnetic tunnel barrier material layer, and a free magnetization material layer; and
each of the at least one filament-forming dielectric material layer is formed such that all top surfaces of a respective underlying array of magnetic tunnel junctions selected from the plurality of arrays of magnetic tunnel junctions is contacted by a bottom surface of a respective one of the at least one filament-forming dielectric material layer.

18. The method of claim 17, wherein at least a subset of the magnetic tunnel junctions selected from the plurality of arrays of magnetic tunnel junctions comprises spin-orbit torque (SOT) magnetic tunnel junctions comprising a respective free magnetization layer in contact with a respective SOT transfer layer.

19. The method of claim 18, wherein the respective SOT transfer layer is formed by depositing and patterning a metal layer such that a sidewall of the metal layer contacts a sidewall of the respective free magnetization layer.

20. The method of claim 18, wherein the respective SOT transfer layer is formed by depositing a metal layer such that the metal layer contacts a bottom surface or a top surface of a respective free magnetization material layer, and by patterning the metal layer such that the metal layer comprises laterally protruding portions that laterally protrude from a sidewall of the respective free magnetization layer.
